(19) United States
(12) Patent Application Publication
(10) Pub. No.: US 2026/0105204 A1
(43) Pub. Date: Apr. 16, 2026

(54) TECHNIQUES FOR USING KNOWLEDGE GRAPHS TO AUTOMATICALLY COMPLETE DRAFT STRUCTURAL DESIGNS

(71) Applicant: AUTODESK, INC., San Francisco, CA (US)

(72) Inventors: Argyrios DELITHANASIS, London (GB); Fikret KALAY, Saint-Jean-Bonnefonds (FR); Shiyu WANG, Caledon (CA); Richard PEDLEY, Birmingham (GB); James DONNELLY, Birmingham (GB); Magdalena KOWALCZYK, San Francisco, CA (US); Fopefoluwa BADEMOSI, Boston, MA (US); James STODDART, Atlanta, GA (US); Damon LAU, New York, NY (US); Peter Thomas STOREY, Utrecht (NL)

(21) Appl. No.: 19/224,589

(22) Filed: May 30, 2025

Related U.S. Application Data
(60) Provisional application No. 63/707,162, filed on Oct. 14, 2024.

(51) Int. Cl. G06F 30/13

(52) U.S. Cl. CPC G06F 30/13

(57) ABSTRACT

One embodiment sets forth a technique for completing computerized representations of physical structures using knowledge graphs. According to some embodiments, the technique includes the steps of generating a knowledge graph that characterizes relationships between various features of computerized representations of physical structures; training one or more machine learning models based on the knowledge graph; receiving a request for adding a selected feature to a computerized representation of a physical structure; generating predicted feature data using the one or more trained machine learning models and the request; and causing the predicted feature data to be rendered at a graphical user interface (GUI) to suggest a predicted feature to be included with the selected feature. Another embodiment sets forth a technique for training machine learning models using knowledge graphs associated with computerized representations of physical structures.

### CROSS-REFERENCE TO RELATED APPLICATIONS

The present application claims the benefit of U.S. Provisional Application titled, “TECHNIQUES FOR AUTOMATED BIM COMPLETION AND ENHANCEMENT USING KNOWLEDGE GRAPHS,” filed on Oct. 14, 2024, and having Ser. No. 63/707,162. The subject matter of this related application is hereby incorporated herein by reference.

### BACKGROUND

### Field of the Various Embodiments

Embodiments of the present disclosure relate generally to computer science, artificial intelligence, and complex software applications, and, more specifically, to techniques for using knowledge graphs to automatically complete draft structural designs.

### Description of the Related Art

Creating computerized designs of buildings and other physical structures can be a meticulous process that demands numerous decisions by humans and numerous manual inputs to a software application. When a proposed design involves the incorporation of various utility systems (e.g., HVAC, running water, etc.) or complicated architectural features, specialized knowledge of various users may be relied upon during the design process. A lack of documentation for implementing certain features can create bottlenecks in the design process, especially as less experienced users may not be able to intuitively iterate certain designs, much less infer intended design objectives from an incomplete design.

Certain technical limitations of existing software are most apparent when iterating a particular design that involves redundant tasks. Such redundant tasks may not only place considerable demands on a human user, but also waste computational resources of any involved computing devices. For example, replicating certain structural features across different parts of a computerized building can involve repeated interactions with an application and cross-referencing any available documentation for guidance. When the structural feature to be replicated is particularly complicated, processing bandwidth and memory can be repeatedly wasted on, for example, redundant geometric calculations.

Another technical limitation of existing design software is the inability to codify implicit relationships between design features without requiring complicated heuristics. In other words, dependencies and relationships between design features (e.g., load-bearing restrictions, orientation of windows, conduit requirements for certain environments, etc.) may only be apparent to an expert designer. When a particular dependent feature is omitted during the beginning of a design process, extensive manual revisions may be required to resolve any errors that have mounted since the omission. Moreover, although heuristics or rules may be codified to some degree, a lack of any intuitive mechanisms for automatically compiling such rules and dependencies yields a considerable amount of manual work for users. These issues are becoming more complicated as new types of building materials and systems become available for incorporating into any given design, thereby creating more potential combinations of building features and more opportunities for important dependencies to be omitted.

As the foregoing illustrates, what is needed in the art are more effective techniques for automatically completing draft structural designs.

### SUMMARY

One embodiment sets forth a computer-implemented method for completing computerized representations of physical structures using knowledge graphs. According to some embodiments, the method includes the steps of generating a knowledge graph that characterizes relationships between various features of computerized representations of physical structures; training one or more machine learning models based on the knowledge graph to generate one or more trained machine learning models; receiving a request for adding a selected feature to a computerized representation of a physical structure; generating predicted feature data using the one or more trained machine learning models and the request; and causing the predicted feature data to be rendered at a graphical user interface (GUI) to suggest a predicted feature to be included with the selected feature at the computerized representation of the physical structure.

One embodiment sets forth a computer-implemented method for training machine learning models using knowledge graphs associated with computerized representations of physical structures. According to some embodiments, the method includes the steps of accessing a knowledge graph associated with a computerized representation of a physical structure with first features; determining second features that are related to the first features of the computerized representation of the physical structure; generating training data based on the first features and the second features for the computerized representation of the physical structure; and training, based on the training data, a machine learning model for generating feature suggestions via a design application.

Other embodiments of the present disclosure include, without limitation, one or more computer-readable media including instructions for performing one or more aspects of the disclosed techniques as well as a computing device for performing one or more aspects of the disclosed techniques.

One technical advantage of the disclosed system and techniques over the prior art is that the disclosed system and techniques simplify the design process for relatively complex structures, such as buildings and other physical structures. Rather than relying on individual geometric calculations to be processed and solved for each manually added design feature, prior designs can be implicitly leveraged to bypass such calculations. Intelligently and proactively instantiating design feature suggestions eliminates the need for a user to individually navigate or scroll through a GUI menu of available design features and then manually select each design feature to incorporate into a draft design. As a result, computational resources, as well as power consumption, are preserved, which might otherwise be consumed by rendering each candidate feature via a graphical processing unit (GPU) or other hardware.

In addition, once the system has been trained to provide feature suggestions, correlations between design data sets can be automatically maintained with little or no manual edits by a user. In some instances, relationships can be inferred for design features that a user might not otherwise recognize or prioritize. This can effectively augment the user design experience by intuiting feature suggestions that may otherwise only appear after further downstream editing by less experienced users. For instance, feature selections that might result in a design becoming more energy efficient, safe, or otherwise more optimized, can be suggested to a more experienced user of the system. Adopting such suggestions can reduce the chance that a downstream reviewer would request edits, thereby further preserving computational resources—such as memory usage—that might otherwise be consumed archiving various design versions.

Yet another technical advantage is that the disclosed techniques enable an entity, such as a building contractor, to ensure subsequent designs can implement any lessons learned from feedback regarding existing designs. For instance, modifications to an existing design can be reflected in knowledge graph data that is utilized to train a machine learning model. When the machine learning model is utilized thereafter for generating suggestions for a future design, feedback regarding a prior design may inherently affect feature suggestions rendered during the future design process. This can streamline any future design process by reducing an amount of time required to manually review past design documentation. This can also result in future design processes being less affected by human error, which could otherwise cause a crucial design feature to be mistakenly omitted, a construction safety step to be bypassed, and/or the like.

These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a network infrastructure configured to implement one or more aspects of various embodiments.

FIG. 2 is a conceptual illustration of an architecture and an informational flow that can be implemented by the management server of FIG. 1, according to various embodiments.

FIGS. 3A-3B show diagrams illustrating how a software application can utilize knowledge graph data to provide suggestions for autocompleting incomplete designs for physical structures, according to various embodiments.

FIG. 4 illustrates a method for using knowledge graphs to automatically complete draft computerized structural designs, according to various embodiments.

FIG. 5 illustrates a method for training machine learning models using knowledge graphs associated with computerized representations of physical structures, according to various embodiments.

FIG. 6 is a more detailed illustration of a computing device that can implement the functionalities of the entities illustrated in FIG. 1, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### System Overview

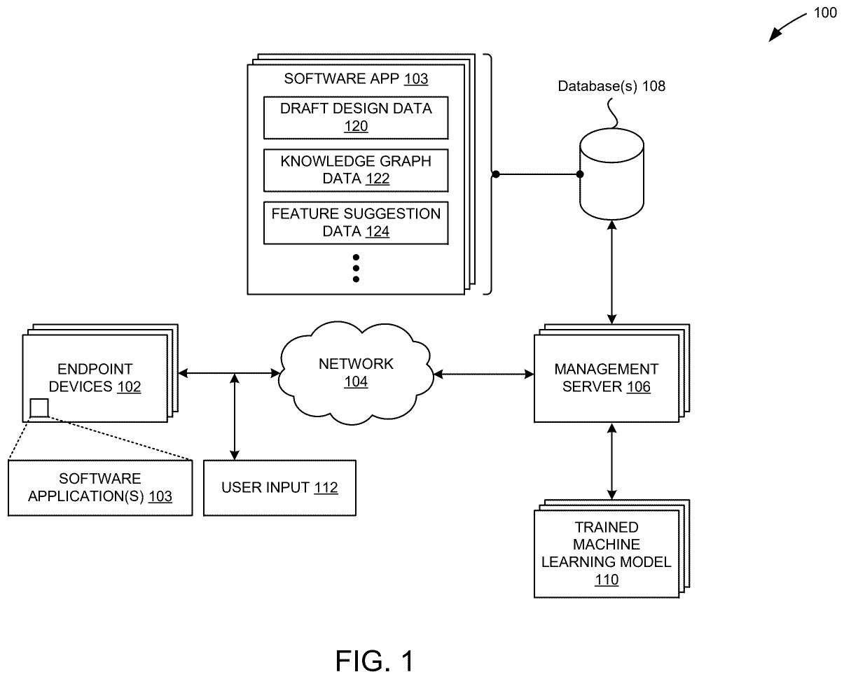

FIG. 1 is a conceptual illustration of a system 100 configured to implement one or more aspects of the various embodiments. As shown, the system 100 includes at least one endpoint device 102, at least one management server 106, at least one database 108, and at least one trained machine learning model 110, which are connected via a communications network 104. The communications network 104 can represent, for example, any technically feasible network or number of networks, including a wide area network (WAN) such as the Internet, a local area network (LAN), a Wi-Fi network, a cellular network, or a combination thereof.

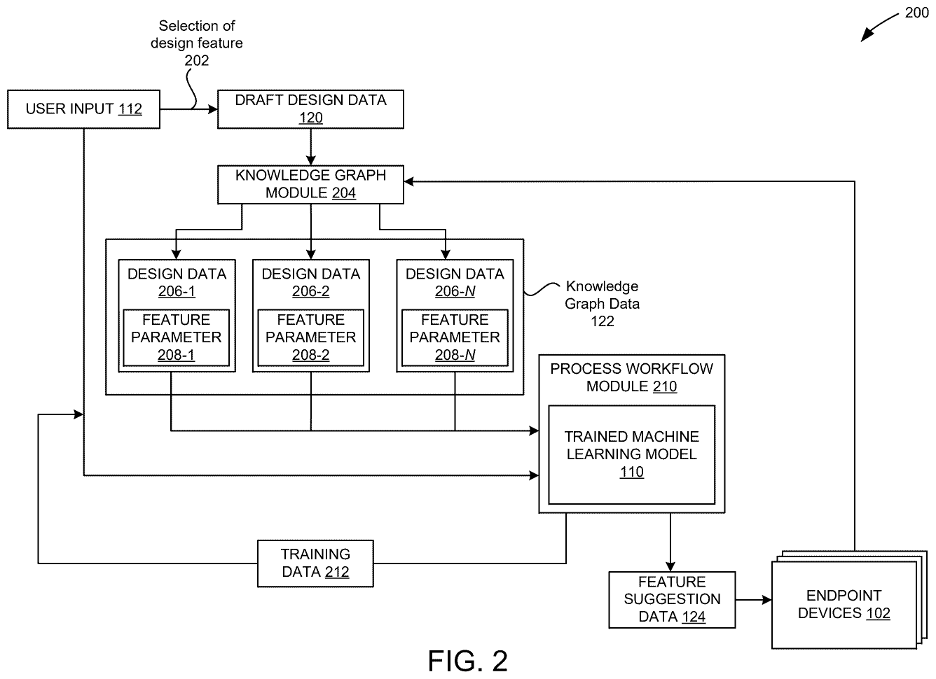

The endpoint device 102 can represent a computing device (e.g., a desktop computing device, a laptop computing device, a mobile computing device, etc.). As shown in FIG. 1, at least one software application 103 can be installed and execute on the endpoint device 102. The software application 103 can represent, for example, a web browser application, a web browser application extension, a design application, and the like. The software application 103 can interface with the management server 106 to access and edit draft design data 120 managed by the management server 106 (and/or other entities not illustrated in FIG. 1). A more detailed explanation of the functionality of the software application 103 is provided below in conjunction with FIGS. 2-4.

The management server 106 can represent a computing device (e.g., a rack server, a blade server, a tower server, etc.). As shown in FIG. 1, the management server 106 can interface with one or more databases 108 that are implemented by the management server 106 (and/or other entities not illustrated in FIG. 1). The databases 108 can include, for at least one software application 103, draft design data 120, knowledge graph data 122, feature suggestion data 124, and/or other information associated with the software application 103. Further details are described in greater detail below in conjunction with FIGS. 2-4.

As described above, the management server 106 can be configured to provide draft design data 120 and feature suggestion data 124 to a software application 103 executing on an endpoint device 102. As also described above, the management server 106 can be configured to receive, from the software application 103, a request for suggested features to be incorporated into a draft design for a physical structure, such as a building. The management server 106 can process one or more of user inputs 112, the draft design data 120, and/or knowledge graph data 122, e.g., using the databases 108, one or more trained machine learning models 110, etc., to generate the feature suggestion data 124. The management server 106 can provide the feature suggestion data 124 to the software application 103, which can then be displayed to the user for selection. A more detailed explanation of the functionality of the management server 106 is provided below in conjunction with FIGS. 2-4.

It will be appreciated that the endpoint device 102, the management server 106, the database 108, and trained machine learning model(s) 110 described in conjunction with FIG. 1 are illustrative, and that variations and modifications are possible. The connection topologies, including the number of processors and memories, may be modified as desired, and, in certain embodiments, one or more components shown in FIG. 1 may not be present, or may be combined into fewer components. Further, in certain embodiments, one or more components shown in FIG. 1 may be implemented as virtualized resources in one or more virtual computing environments and/or cloud computing environments.

### Auto-Generation of Suggested Features for Computerized Structural Designs

FIG. 2 is a conceptual illustration of an architecture and an informational flow that can be implemented by the management server 106 of FIG. 1, according to various embodiments. As shown in FIG. 2, the management server 106 can receive, from a software application 103 executing on an endpoint device 102, a user input 122 that can characterize a selection of a feature 202 to be included with draft design data 120 for a computerized physical structure. The software application 103 can have access to a variety of different completed or incomplete designs for physical structures such as a building or other architectural design.

The user input 112 can be directed to a draft building design characterized by draft design data 120, which can correspond to an empty data file, a file with some amount of data, and/or a file representing a completed design. In this way, the system 200 can provide autocomplete suggestions for any particular stage of a design process, even after completion. In some embodiments, the user input 112 can be processed for generating the draft design data 120. The draft design data 120 can, in some instances, represent one or more features to be incorporated into a computerized draft of a physical structure. In some implementations, the draft design data 120 can be processed for updating a knowledge graph associated with a physical structure. For example, a knowledge graph module 204 can process the draft design data 120 to generate knowledge graph data 122. The knowledge graph data 122 can characterize one or more features of a computerized physical structure, properties of those features, and/or relationships between those features and any other associated features.

As shown in FIG. 2, the knowledge graph module 204 can generate various instances of design data and feature parameters as part of a knowledge graph for the computerized physical structure. As one non-limiting example, when the user input 112 corresponds to a selection of an outdoor light to be incorporated on the outside of the computerized physical structure, design data 206-1 can be generated for identifying the selected outdoor light. The design data 206-1 can include one or more feature parameters 208-1 that can characterize relationships between components of the selected outdoor light, between components of the selected outdoor light and features of the computerized physical structure, and/or any other relationships that can be associated with the selected outdoor light.

In some instances, however, a selected feature may have incomplete data or otherwise be missing information regarding relationships between the selected feature and one or more features of the draft design. For example, the selected outdoor light may be defined as having an integrated junction box for receiving certain types of outdoor conduit. Therefore, although the feature parameter 208-1 may identify this integrated junction box, the outdoor conduit may not be a feature of the draft design at this point in the design process. Moreover, other features of the selected outdoor light may also be missing from the design data 206-1, such as light temperature, surface paint color, surface material, and/or any other feature that can be associated with an outdoor light.

The knowledge graph data 122 that is associated with the draft design data 120 can be processed by a process workflow module 210 of the system 200. The process workflow module 210 can include or access one or more trained machine learning models 110 that can be utilized for generating feature suggestion data 124. The one or more trained machine learning models 110 can be trained using training data 212 that is based on knowledge graph data for other designs available to the system 200. For example, other draft designs or other completed designs for computerized structures can be characterized by other knowledge graphs accessible to the process workflow module 210 or system 200. This other knowledge graph data can indicate relationships between features of existing designs, draft designs, and/or other computerized designs for one or more objects.

In some embodiments, available knowledge graph data 122 can be utilized to generate embeddings to be mapped to one or more latent spaces. In this way, input data 112 and/or knowledge graph data 122 can be processed by the process workflow module 210 for generating embeddings corresponding to the user input 112 and/or the knowledge graph data 122. Based on the mapping of these embeddings in latent space(s), feature suggestion data 124 can be generated to provide suggestions in response to receiving the user input 112.

For example, in response to receiving the selection of the outdoor light, the process workflow module 210 can generate an embedding corresponding to the selected outdoor light. In some instances, this input embedding may be mapped to a latent space within a threshold distance of other existing embeddings. Those other existing embeddings can correspond to certain design features, relationships, or other information, specified in other knowledge graphs or other computerized designs. For example, the input embedding for the selected outdoor light may be within a threshold distance of an embedding for a particular type of conduit and an embedding for another outdoor light that architects have considered to be complementary to the selected outdoor light. The conduit and the other outdoor light can then be characterized by suggestion data 124 and communicated to an endpoint device 102 that is accessing the software application 103.

In some instances, the feature suggestion data 124 can be processed by the software application for rendering selectable graphical elements corresponding to the suggested features. For example, one or more images representing the particular conduit and the other outdoor light can be rendered at a display interface of an endpoint device 102 that is accessing the software application 103. The user can then select one or more of the images for incorporating into the draft design. Alternatively, or additionally, when a particular threshold, rank, or other metric is determined for a feature suggestion, and the rank or metric satisfies one or more conditions, the suggested feature, or multiple suggestion features, can be automatically incorporated into the draft design without input from the user.

In some embodiments, training data 212 can be generated to characterize a user selection of a particular suggested feature and the user input 112 that resulted in the particular feature being suggested. This training data can then be utilized for further training the one or more trained machine learning models 110 for facilitating accurate suggestions for completing subsequent draft designs. In some embodiments, the process workflow module 210 can generate training data that is based on features, metadata, and/or other information stored in association with one or more computerized representations of physical structures. In some embodiments, the features can be identified in knowledge graph data 122, which can characterize one or more knowledge graphs and can include metadata that is stored in association with the features.

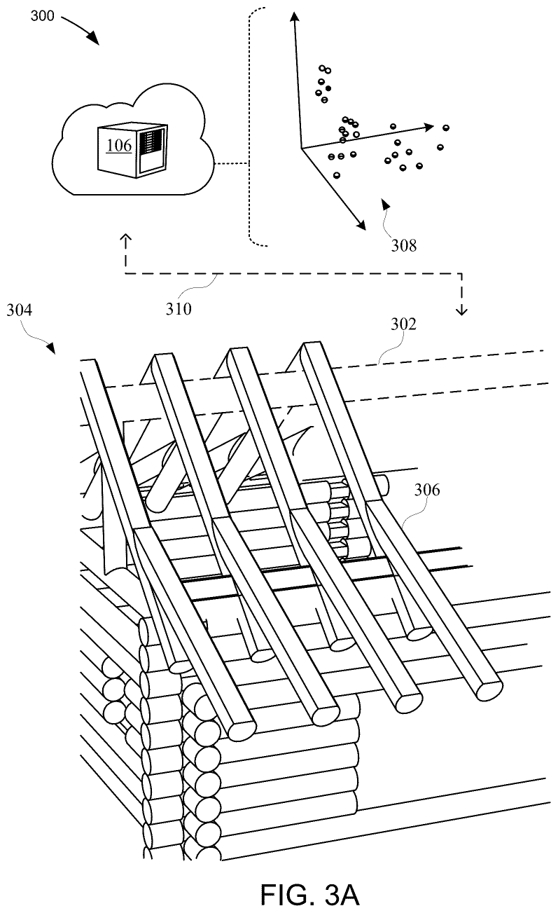

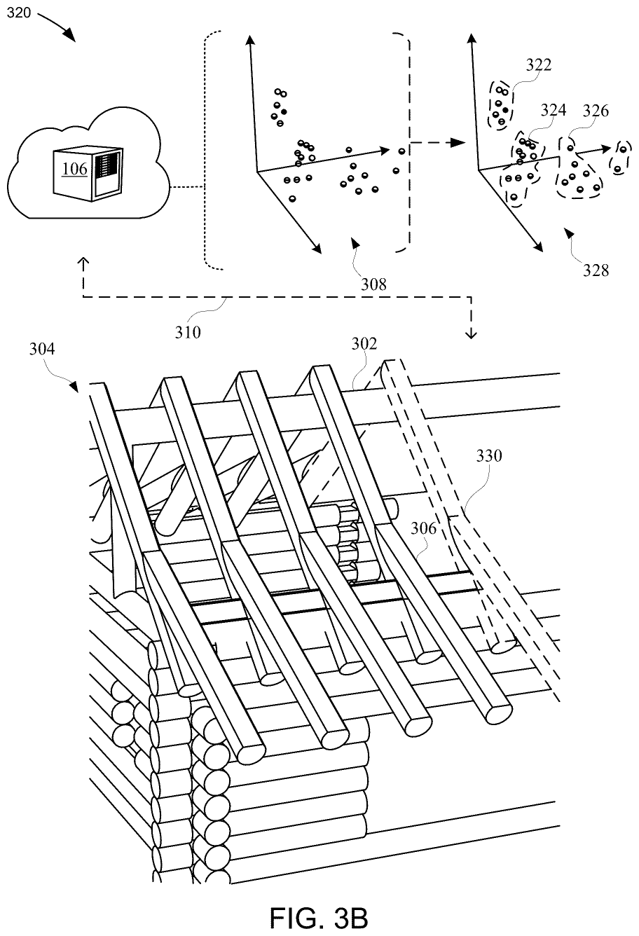

In some embodiments, the training data can identify labeled data that indicates initial features that were selected by a user and any features that were selected subsequent to those initial features for a design. For instance, temporal data can be stored in association with features of a computerized representation of a physical structure to distinguish between when each feature was selected for incorporation into the physical structure. As an example, and as illustrated in FIG. 3A, training data can indicate when a user interacted with a design application to add a first feature 302 to a computerized representation of a physical structure 304. The training data can also indicate when a user interacted with a design application to add a second feature 306 to the computerized representation of the physical structure 304.

Alternatively, or additionally, the training data can characterize a structural dependency between the first feature 302 and the second feature 306. Using the training data, the management server 106 can generate embeddings to be mapped into a latent space 308, and/or otherwise train one or more trained machine learning models. In some embodiments, training the one or more machine learning models can involve arranging feature data according to any relationship between first features and second features. This arrangement can then be utilized for determining weights and/or biases for process inputs to a neural network, decision tree, or other artificial intelligence.

In some implementations, first features, second features, etc., can refer to material layers selected for a physical structure, and/or metadata stored in association with one or more features and/or a knowledge graph. For example, a first feature can refer to a rule with which the physical structure and/or the design application must comply, and a second feature can refer to a physical feature of the computerized representation of the physical structure 304. In some embodiments, the one or more rules can include an environmental limitation, an energy limitation, and/or a material limitation intended for a physical structure. For example, an environmental limitation can include, but is not limited to, an amount of carbon estimated to be consumed when constructing the physical structure, and an energy limitation can be an amount of energy any utilities for the physical structure may consume during operation of the physical structure. In such instances, a second feature can be a particular physical feature that satisfies the energy limitation and/or an upper limit on carbon consumption.

Alternatively, or additionally, a first feature can refer to a structural component of a computerized building and a second feature can be based on metadata stored in association with the first feature. The metadata can indicate, for example, a relationship between the first feature and another feature of the computerized building, an environment of the computerized building, and/or an owner of the computerized building.

It is noted that the foregoing examples are not meant to be limiting, and that the described system 200 can include any amount, type, form, etc., of data, at any level of granularity, consistent with the scope of this disclosure.

FIGS. 3A-3B show a diagram 300 and a diagram 320 illustrating how the software application 103 can utilize knowledge graph data 122 to provide suggestions for autocompleting incomplete designs for physical structures, according to various embodiments. The knowledge graph data 122 can characterize a variety of completed or incomplete designs for physical structures, such as buildings or other structures. The software application 103 can provide an interface for adding features to a 3D rendering of the structure. For example, a touch interface or other input device can be used to drag and drop features onto an incomplete design as input 310 to the software application 103. In some instances, a user might drag and drop the second feature 306 onto the first feature 302, or drag and drop the first feature 302 onto the second feature 306 via a graphical user interface (GUI) of the software application 103. Data characterizing each feature and their relationship(s) can be generated and stored with knowledge graph data 122 for the computerized representation of the physical structure 304.

During an ongoing interaction, or a separate interaction with the user, the software application 103 can initiate processing of the knowledge graph data 122 to automatically identify suggestions for additional elements to add to an incomplete design. In furtherance of the above example, feature parameter data 208-N can be processed along with other data that characterizes features of the physical structure 304. In some implementations, this processing can involve generating embeddings using one or more trained machine learning models that have been trained using one or more knowledge graphs to generate training data 212.

As an example, a first feature embedding 322 and a second feature embedding 326 can be mapped to a latent space 328 for determining a feature suggestion to present to a user of the software application 103. A distance between these embeddings and one or more other feature embeddings can be determined for the latent space. When the distance in latent space satisfies a threshold distance for a particular feature embedding 324, a particular feature corresponding to that particular feature embedding 324 can be rendered at a GUI of the software application 103.

In some embodiments, features of different building designs may be mapped as embeddings in the latent space 328. For instance, features of energy-efficient designs may correspond to embeddings that are relatively close to one another in the latent space. Alternatively, or additionally, designs with comparable architectural styles or intended uses may also have embeddings located near one another in the latent space 328. Alternatively, or additionally, embeddings representing dissimilar designs, uses, and/or energy profiles may be located relatively further apart in the latent space 328. Thus, mapped embeddings may be clustered due to shared or similar characteristic(s) such as similar creators or common features among various building designs. As a result, suggestions provided via the software application 103 can be based on the latent proximity within the latent space between the embedding of the incomplete design and embeddings of completed designs used as training data 212.

As a non-limiting example, a user interacting with the software application 103 to create a 3D rendering of the computerized representation of the physical structure 304 may first complete a frame feature (e.g., first feature 302) and then begin adding each roof feature (e.g., second feature 306). As the user selects the roof features, the software application 103 can process the input and generate or update a particular feature embedding 324. This particular feature embedding 324 can then be mapped into the latent space 328 alongside existing embeddings. If the management server 106 detects that the particular feature embedding 324 is within a threshold distance of an existing embedding (e.g., second feature embedding 326), a feature suggestion 330 can be rendered for the user to select, as illustrated in diagram 320 of FIG. 3B.

In some implementations, multiple suggested features 330 can be displayed simultaneously within the software application 103 GUI as the user works with one or more design files. One or more trained machine learning models can process the user input data 310 to identify features that might be relevant or beneficial for streamlining the design process for the computerized representation of the physical structure 304. Based on this processing, the software application 103 can render a suggestion interface that includes multiple graphical representations of possible features. Additional data, such as natural language descriptions or images, can accompany these suggestions to indicate how each might impact the current design and/or rules for the design.

In some embodiments, the software application 103 can alert the user to other features in response to a particular suggestion being accepted or otherwise incorporated into the physical structure 304. For example, completing a roof feature of the physical structure 304 can cause the software application 103 to suggest adding a power converter feature or energy storage feature to the physical structure 103. These secondary suggestions can also be identified using the trained machine learning model(s) 110, and how the user interacts with those secondary suggestions can result in further training of the trained machine learning model(s) 110.

It is noted that the user interfaces illustrated in FIGS. 3A-3B are not meant to be limiting, and that the user interfaces can include any amount, type, form, etc., of UI element(s), at any level of granularity, consistent with the scope of this disclosure.

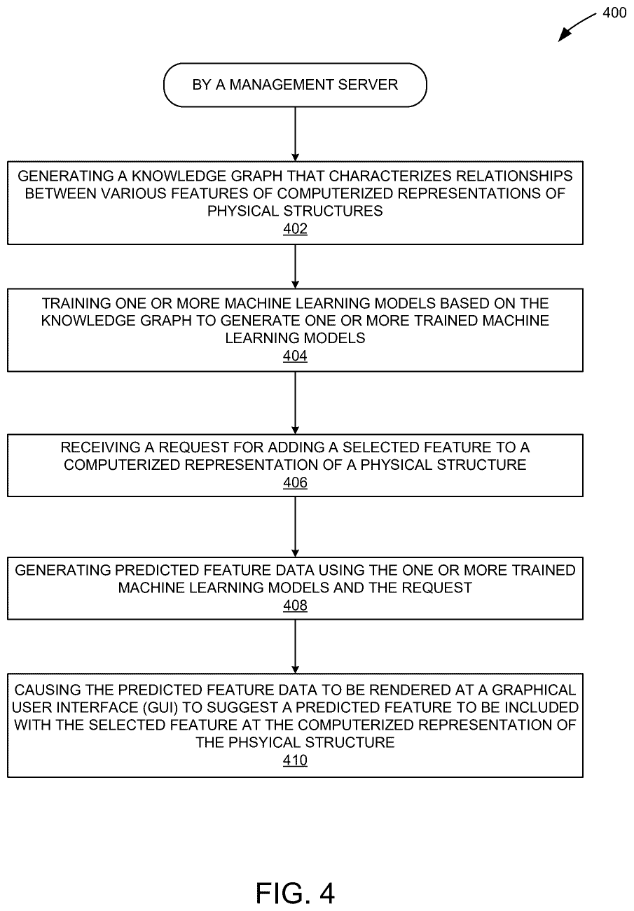

FIG. 4 illustrates a method 400 for completing computerized representations of physical structures using knowledge graphs, according to various embodiments. As shown in FIG. 4, the method 400 begins at step 402, where the management server 106 generates a knowledge graph that characterizes relationships between various features of computerized representations of physical structures (e.g., as described above in conjunction with FIGS. 1-3).

At step 404, the management server 106 trains one or more machine learning models based on the knowledge graph to generate one or more trained machine learning models (e.g., as described above in conjunction with FIGS. 1-3). At step 406, the management server 106 receives a request for adding a selected feature to a computerized representation of a physical structure (e.g., as described above in conjunction with FIGS. 1-3).

At step 408, the management server 106 causes the predicted feature data to be rendered at a graphical user interface (GUI) to suggest a predicted feature to be included with the selected feature at the computerized representation of the physical structure (e.g., as described above in conjunction with FIGS. 1-3).

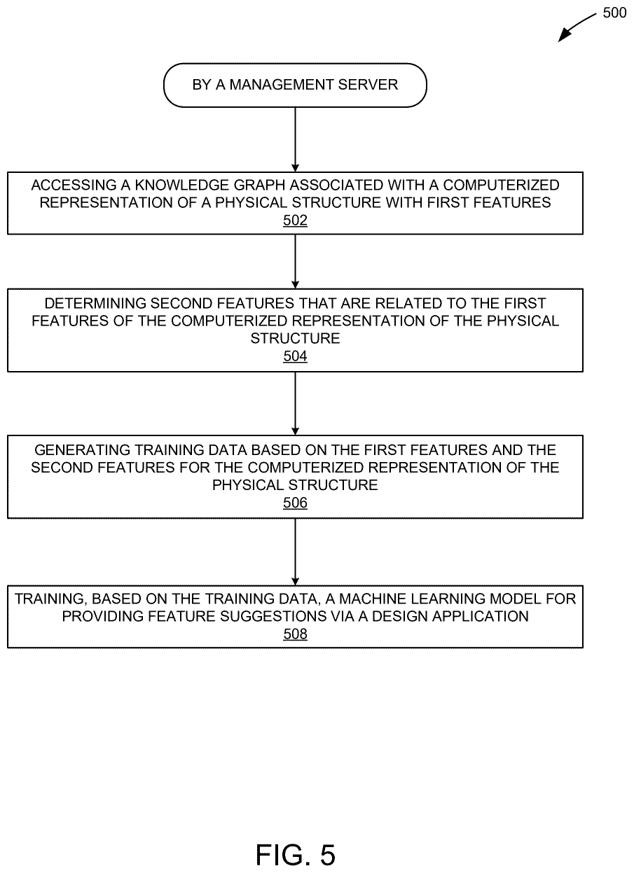

FIG. 5 illustrates a method 500 for training machine learning models using knowledge graphs associated with computerized representations of physical structures, according to various embodiments. As shown in FIG. 5, the method 500 begins at step 502, where the management server 106 accesses a knowledge graph associated with a computerized representation of a physical structure with first features (e.g., as described above in conjunction with FIGS. 1-3).

At step 504, the management server 106 determines second features that are related to the first features of the computerized representation of the physical structure (e.g., as described above in conjunction with FIGS. 1-3). At step 506, the management server 106 generates training data based on the first features and the second features for the computerized representation of the physical structure (e.g., as described above in conjunction with FIGS. 1-3).

At step 508, the management server 106 trains, based on the training data, a machine learning model for providing feature suggestions via a design application (e.g., as described above in conjunction with FIGS. 1-3).

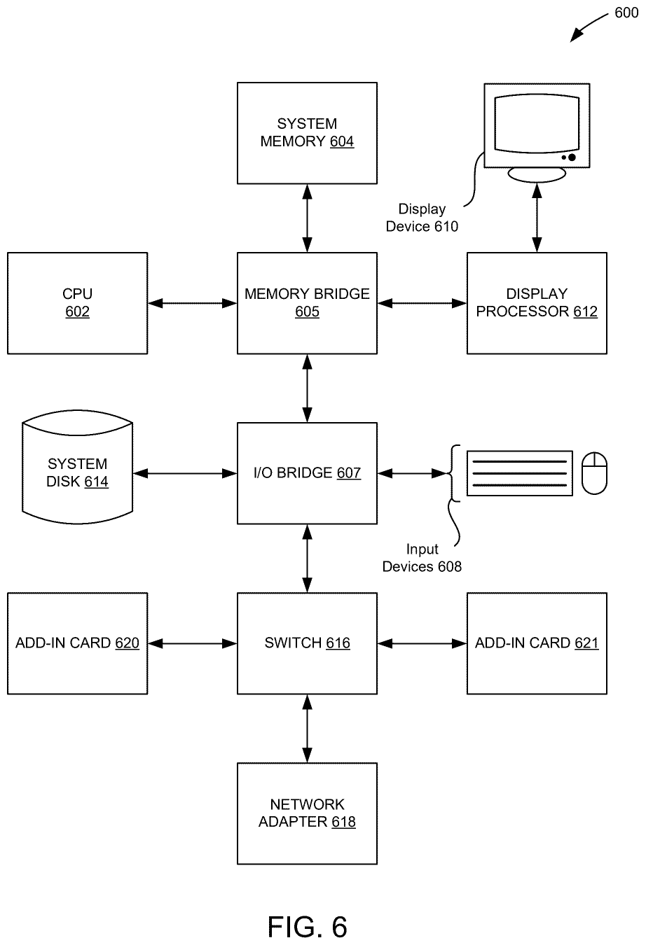

FIG. 6 is a more detailed illustration of a computing device that can implement the functionalities of the entities illustrated in FIG. 1, according to various embodiments. This figure in no way limits or is intended to limit the scope of the various embodiments. In various implementations, system 600 may be an augmented reality, virtual reality, or mixed reality system or device, a personal computer, video game console, personal digital assistant, mobile phone, mobile device or any other device suitable for practicing the various embodiments. Further, in various embodiments, any combination of two or more systems 600 may be coupled together to practice one or more aspects of the various embodiments.

As shown, system 600 includes a central processing unit (CPU) 602 and a system memory 604 communicating via a bus path that may include a memory bridge 605. CPU 602 includes one or more processing cores, and, in operation, CPU 602 is the master processor of system 600, controlling and coordinating operations of other system components. System memory 604 stores software applications and data for use by CPU 602. CPU 602 runs software applications and optionally an operating system. Memory bridge 605, which may be, e.g., a Northbridge chip, is connected via a bus or other communication path (e.g., a HyperTransport link) to an I/O (input/output) bridge 607. I/O bridge 607, which may be, e.g., a Southbridge chip, receives user input from one or more user input devices 608 (e.g., keyboard, mouse, joystick, digitizer tablets, touch pads, touch screens, still or video cameras, motion sensors, and/or microphones) and forwards the input to CPU 602 via memory bridge 605.

A display processor 612 is coupled to memory bridge 605 via a bus or other communication path (e.g., a PCI Express, Accelerated Graphics Port, or HyperTransport link); in one embodiment display processor 612 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 604.

Display processor 612 periodically delivers pixels to a display device 610 (e.g., a screen or conventional CRT, plasma, OLED, SED or LCD based monitor or television). Additionally, display processor 612 may output pixels to film recorders adapted to reproduce computer generated images on photographic film. Display processor 612 can provide display device 610 with an analog or digital signal. In various embodiments, one or more of the various graphical user interfaces set forth in FIG. 3 are displayed to one or more users via display device 610, and the one or more users can input data into and receive visual output from those various graphical user interfaces.

A system disk 614 is also connected to I/O bridge 607 and may be configured to store content and applications and data for use by CPU 602 and display processor 612. System disk 614 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 616 provides connections between I/O bridge 607 and other components such as a network adapter 618 and various add-in cards 620 and 621. Network adapter 618 allows system 600 to communicate with other systems via an electronic communications network, and may include wired or wireless communication over local area networks and wide area networks such as the Internet.

Other components (not shown), including USB or other port connections, film recording devices, and the like, may also be connected to I/O bridge 607. For example, an audio processor may be used to generate analog or digital audio output from instructions and/or data provided by CPU 602, system memory 604, or system disk 614. Communication paths interconnecting the various components in FIG. 6 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 612 incorporates circuitry optimized for graphics and 3D processing, including, for example, visual output circuitry, and constitutes a graphics processing unit (GPU). In another embodiment, display processor 612 incorporates circuitry optimized for general purpose processing. In yet another embodiment, display processor 612 may be integrated with one or more other system elements, such as the memory bridge 605, CPU 602, and I/O bridge 607 to form a system on chip (SoC). In still further embodiments, display processor 612 is omitted and software executed by CPU 602 performs the functions of display processor 612.

Pixel data can be provided to display processor 612 directly from CPU 602. In some embodiments, instructions and/or data representing a scene are provided to a render farm or a set of server computers, each similar to system 600, via network adapter 618 or system disk 614. The render farm generates one or more rendered images of the scene using the provided instructions and/or data. These rendered images may be stored on computer-readable media in a digital format and optionally returned to system 600 for display. Similarly, stereo image pairs processed by display processor 612 may be output to other systems for display, stored in system disk 614, or stored on computer-readable media in a digital format.

Alternatively, CPU 602 provides display processor 612 with data and/or instructions defining the desired output images, from which display processor 612 generates the pixel data of one or more output images, including characterizing and/or adjusting the offset between stereo image pairs. The data and/or instructions defining the desired output images can be stored in system memory 604 or graphics memory within display processor 612. In an embodiment, display processor 612 includes 3D rendering capabilities for generating pixel data for output images from instructions and data defining the geometry, lighting shading, texturing, motion, and/or camera parameters for a scene. Display processor 612 can further include one or more programmable execution units capable of executing shader programs, tone mapping programs, and the like.

Further, in other embodiments, CPU 602 or display processor 612 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 602, display processor 612, or one or more other processing devices or any combination of these different processors.

CPU 602, render farm, and/or display processor 612 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 600 may be a robot or robotic device and may include CPU 602 and/or other processing units or devices and system memory 604. In such embodiments, system 600 may or may not include other elements shown in FIG. 6. System memory 604 and/or other memory units or devices in system 600 may include instructions that, when executed, cause the robot or robotic device represented by system 600 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 604 is connected to CPU 602 directly rather than through a bridge, and other devices communicate with system memory 604 via memory bridge 605 and CPU 602. In other alternative topologies display processor 612 is connected to I/O bridge 607 or directly to CPU 602, rather than to memory bridge 605. In still other embodiments, I/O bridge 607 and memory bridge 605 might be integrated into a single chip. The particular components shown herein are optional; for instance, any number of add-in cards or peripheral devices might be supported. In some embodiments, switch 616 is eliminated, and network adapter 618 and add-in cards 620, 621 connect directly to I/O bridge 607.

In sum, the disclosed system and techniques enable users to receive suggestions for auto-completing a design for a physical structure by using machine learning models that are trained using knowledge graphs. The system allows users to receive generative suggestions while interacting with the design application in furtherance of completing a computerized representation of a physical structure. The system can receive an input from a user in furtherance of editing a design for a physical structure—and, in response, the system can generate one or more suggestions using one or more trained machine learning models. Such suggestions can include additional physical features to be attached to the physical structure and/or other attributes that may modify the physical structure. Providing suggestions in this way can mitigate waste of computational resources that might otherwise occur by performing redundant tasks during design processes.

Training data utilized for training the machine learning models can be generated from one or more knowledge graphs that can characterize relationships between features of existing designs for physical structures. The knowledge graphs can identify physical features of a physical structure, as well as metadata that describes dependencies between those features and/or other relationships between those features. Knowledge graph data can be arranged according to these relationships in furtherance of optimizing a trained machine learning model for use when generating suggestions for a draft design. Such relationships can include temporal relationships, structural dependencies, or other types of relationships that can be associated with designing a physical structure. Training machine learning models to leverage the robust information embodied in knowledge graphs can provide for more accurate suggestions, thereby further reducing time to completion for a physical structure, such as a building or other physical object.

One technical advantage of the disclosed system and techniques over the prior art is that the disclosed system and techniques simplify the design process for relatively complex structures, such as buildings and other physical structures. Rather than relying on individual geometric calculations to be processed and solved for each manually added design feature, prior designs can be implicitly leveraged to bypass such calculations. Intelligently and proactively instantiating design feature suggestions eliminates the need for a user to individually navigate or scroll through a GUI menu of available design features and then manually select each design feature to incorporate into a draft design. As a result, computational resources, as well as power consumption, are preserved, which might otherwise be consumed by rendering each candidate feature via a graphical processing unit (GPU) or other hardware.

In addition, once the system has been trained to provide feature suggestions, correlations between design data sets can be automatically maintained with little or no manual edits by a user. In some instances, relationships can be inferred for design features that a user might not otherwise recognize or prioritize. This can effectively augment the user design experience by intuiting feature suggestions that may otherwise only appear after further downstream editing by more inexperienced users. For instance, feature selections that might result in a design becoming more energy efficient, safe, or otherwise more optimized, can be suggested to a more experienced user of the system. Adopting such suggestions can reduce the chance that a downstream reviewer would request edits, thereby further preserving computational resources—such as memory usage—that might otherwise be consumed archiving various design versions.

Yet another technical advantage is that the disclosed techniques enable an entity, such as a building contractor, to ensure subsequent designs can implement any lessons learned from feedback regarding existing designs. For instance, modifications to an existing design can be reflected in knowledge graph data that is utilized to train a machine learning model. When the machine learning model is utilized thereafter for generating suggestions for a future design, feedback regarding a prior design may inherently affect feature suggestions rendered during the future design process. This can streamline any future design process by reducing an amount of time required to manually review past design documentation. This can also result in future design processes being less affected by human error, which could otherwise cause a crucial design feature to be mistakenly omitted, a construction safety step to be bypassed, and/or the like.

1. In some embodiments, a computer-implemented method for completing computerized representations of physical structures using knowledge graphs comprises generating a knowledge graph that characterizes relationships between various features of computerized representations of physical structures; training one or more machine learning models based on the knowledge graph to generate one or more trained machine learning models; receiving a request for adding a selected feature to a computerized representation of a physical structure; generating predicted feature data using the one or more trained machine learning models and the request; and causing the predicted feature data to be rendered at a graphical user interface (GUI) to suggest a predicted feature to be included with the selected feature at the computerized representation of the physical structure.

2. The computer-implemented method of clause 1, wherein the predicted feature data characterize the predicted feature, which is included in with the various features identified in the knowledge graph.

3. The computer-implemented method of clause 1, wherein the knowledge graph characterizes a relationship between layers of material of the computerized representation of the physical structure; and the request identifies a particular layer of the layers of material to be included with the computerized representation of the physical structure.

4. The computer-implemented method of clause 1, wherein the request corresponds to an input gesture involving the user dragging a building material GUI element towards the computerized representation of the physical structure; and the predicted feature data is generated in response to building material GUI element contacting the computerized representation of the physical structure.

5. The computer-implemented method of clause 1, wherein the predicted feature data characterizes multiple different suggested features for a user to select from for including with the computerized representation of the physical structure.

6. The computer-implemented method of clause 1, further comprising, subsequent to causing the predicted feature data to be rendered at the GUI, receiving a selection of a selectable GUI element that is rendered at the GUI and corresponds to the predicted feature data rendered at the GUI.

7. The computer-implemented method of clause 6, further comprising, subsequent to receiving the selection of the selectable GUI element, causing the predicted feature to rendered as connected to the selected feature and the computerized representation of the physical structure.

8. The computer-implemented method of clause 1, further comprising, subsequent to causing the predicted feature data to be rendered at the GUI, causing the one or more trained machine learning models to be further trained according to whether a user interacts with the predicted feature data rendered at the GUI.

9. The computer-implemented method of clause 1, wherein the predicted feature corresponds to an internal feature relative to the selected feature and the computerized representation of the physical structure.

10.The computer-implemented method of clause 1, further comprising, subsequent to causing the predicted feature data to be rendered at the GUI, causing a particular knowledge graph for the computerized representation of the physical structure.

11. In some embodiments, one or more non-transitory computer readable media store instructions that, when executed by one or more processors, cause the one or more processors to complete computerized representations of physical structures using knowledge graphs, by performing the operations of generating a knowledge graph that characterizes relationships between various features of computerized representations of physical structures; training one or more machine learning models based on the knowledge graph to generate one or more trained machine learning models; receiving a request for adding a selected feature to a computerized representation of a physical structure; generating predicted feature data using the one or more trained machine learning models and the request; and causing the predicted feature data to be rendered at a graphical user interface (GUI) to suggest a predicted feature to be included with the selected feature at the computerized representation of the physical structure.

12.The one or more non-transitory computer readable media clause 11, further comprising, subsequent to receiving the request for adding the selected feature to the computerized representation of the physical structure, generating updated knowledge graph that characterizes a relationship between the physical structure and the selected feature.

13.The one or more non-transitory computer readable media clause 12, wherein the selected feature corresponds to a wall, floor, or ceiling for the physical structure and the predicted feature corresponds to an additional wall, an additional floor, or an additional ceiling for the physical structure.

14.The one or more non-transitory computer readable media clause 11, wherein the predicted feature is rendered as attached to or abutting the computerized representation of the physical structure.

15.The one or more non-transitory computer readable media clause 11, wherein the predicted feature data characterize the predicted feature, which is included in with the various features identified in the knowledge graph.

16.The one or more non-transitory computer readable media clause 11, wherein the knowledge graph characterizes a relationship between layers of material of the computerized representation of the physical structure; and the request identifies a particular layer of the layers of material to be included with the computerized representation of the physical structure.

17.The one or more non-transitory computer readable media clause 11, wherein the request corresponds to an input gesture involving the user dragging a building material GUI element towards the computerized representation of the physical structure; and the predicted feature data is generated in response to building material GUI element contacting the computerized representation of the physical structure.

18.The one or more non-transitory computer readable media clause 11, wherein the predicted feature data characterizes multiple different suggested features for a user to select from for including with the computerized representation of the physical structure.

19.The one or more non-transitory computer readable media clause 11, further comprising, subsequent to causing the predicted feature data to be rendered at the GUI, receiving a selection of a selectable GUI element that is rendered at the GUI and corresponds to the predicted feature data rendered at the GUI.

20.In some embodiments, a computer system comprises one or more memories that include instructions, and one or more processors that are coupled to the one or more memories and that, when executing the instructions, are configured to perform the operations of generating knowledge graph that characterizes relationships between various features of computerized representations of physical structures; training one or more machine learning models based on the knowledge graph to generate one or more trained machine learning models; receiving a request for adding a selected feature to a computerized representation of a physical structure; generating predicted feature data using the one or more trained machine learning models and the request; and causing the predicted feature data to be rendered at a graphical user interface (GUI) to suggest a predicted feature to be included with the selected feature at the computerized representation of the physical structure.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The invention has been described above with reference to specific embodiments. Persons of ordinary skill in the art, however, will understand that various modifications and changes may be made thereto without departing from the broader spirit and scope of the invention as set forth in the appended claims. For example, and without limitation, although many of the descriptions herein refer to specific types of I/O devices that may acquire data associated with an object of interest, persons skilled in the art will appreciate that the systems and techniques described herein are applicable to other types of I/O devices. The foregoing description and drawings are, accordingly, to be regarded in an illustrative rather than a restrictive sense.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for completing computerized representations of physical structures using knowledge graphs, the method comprising:
generating a knowledge graph that characterizes relationships between various features of computerized representations of physical structures;
training one or more machine learning models based on the knowledge graph to generate one or more trained machine learning models;
receiving a request for adding a selected feature to a computerized representation of a physical structure;
generating predicted feature data using the one or more trained machine learning models and the request; and
causing the predicted feature data to be rendered at a graphical user interface (GUI) to suggest a predicted feature to be included with the selected feature at the computerized representation of the physical structure.

2. The computer-implemented method of claim 1, wherein:
the predicted feature data characterize the predicted feature, which is included in with the various features identified in the knowledge graph.

3. The computer-implemented method of claim 1, wherein:
the knowledge graph characterizes a relationship between layers of material of the computerized representation of the physical structure; and
the request identifies a particular layer of the layers of material to be included with the computerized representation of the physical structure.

4. The computer-implemented method of claim 1, wherein:
the request corresponds to an input gesture involving the user dragging a building material GUI element towards the computerized representation of the physical structure; and
the predicted feature data is generated in response to building material GUI element contacting the computerized representation of the physical structure.

5. The computer-implemented method of claim 1, wherein:
the predicted feature data characterizes multiple different suggested features for a user to select from for including with the computerized representation of the physical structure.

6. The computer-implemented method of claim 1, further comprising, subsequent to causing the predicted feature data to be rendered at the GUI, receiving a selection of a selectable GUI element that is rendered at the GUI and corresponds to the predicted feature data rendered at the GUI.

7. The computer-implemented method of claim 6, further comprising, subsequent to receiving the selection of the selectable GUI element, causing the predicted feature to rendered as connected to the selected feature and the computerized representation of the physical structure.

8. The computer-implemented method of claim 1, further comprising, subsequent to causing the predicted feature data to be rendered at the GUI, causing the one or more trained machine learning models to be further trained according to whether a user interacts with the predicted feature data rendered at the GUI.

9. The computer-implemented method of claim 1, wherein:
the predicted feature corresponds to an internal feature relative to the selected feature and the computerized representation of the physical structure.

10. The computer-implemented method of claim 1, further comprising, subsequent to causing the predicted feature data to be rendered at the GUI, causing a particular knowledge graph for the computerized representation of the physical structure.

11. One or more non-transitory computer readable media storing instructions that, when executed by one or more processors, cause the one or more processors to complete computerized representations of physical structures using knowledge graphs, by performing the operations of:
generating a knowledge graph that characterizes relationships between various features of computerized representations of physical structures;
training one or more machine learning models based on the knowledge graph to generate one or more trained machine learning models;
receiving a request for adding a selected feature to a computerized representation of a physical structure;
generating predicted feature data using the one or more trained machine learning models and the request; and
causing the predicted feature data to be rendered at a graphical user interface (GUI) to suggest a predicted feature to be included with the selected feature at the computerized representation of the physical structure.

12. The one or more non-transitory computer readable media claim 11, further comprising, subsequent to receiving the request for adding the selected feature to the computerized representation of the physical structure, generating updated knowledge graph that characterizes a relationship between the physical structure and the selected feature.

13. The one or more non-transitory computer readable media claim 12, wherein:
the selected feature corresponds to a wall, floor, or ceiling for the physical structure and the predicted feature corresponds to an additional wall, an additional floor, or an additional ceiling for the physical structure.

14. The one or more non-transitory computer readable media claim 11, wherein:
the predicted feature is rendered as attached to or abutting the computerized representation of the physical structure.

15. The one or more non-transitory computer readable media claim 11, wherein:
the predicted feature data characterize the predicted feature, which is included in with the various features identified in the knowledge graph.

16. The one or more non-transitory computer readable media claim 11, wherein:
the knowledge graph characterizes a relationship between layers of material of the computerized representation of the physical structure; and
the request identifies a particular layer of the layers of material to be included with the computerized representation of the physical structure.

17. The one or more non-transitory computer readable media claim 11, wherein:
the request corresponds to an input gesture involving the user dragging a building material GUI element towards the computerized representation of the physical structure; and
the predicted feature data is generated in response to building material GUI element contacting the computerized representation of the physical structure.

18. The one or more non-transitory computer readable media claim 11, wherein:
the predicted feature data characterizes multiple different suggested features for a user to select from for including with the computerized representation of the physical structure.

19. The one or more non-transitory computer readable media claim 11, further comprising, subsequent to causing the predicted feature data to be rendered at the GUI, receiving a selection of a selectable GUI element that is rendered at the GUI and corresponds to the predicted feature data rendered at the GUI.

20. A computer system, comprising:
one or more memories that include instructions; and
one or more processors that are coupled to the one or more memories and, when executing the instructions, are configured to perform the operations of:
generating knowledge graph that characterizes relationships between various features of computerized representations of physical structures;
training one or more machine learning models based on the knowledge graph to generate one or more trained machine learning models;
receiving a request for adding a selected feature to a computerized representation of a physical structure;
generating predicted feature data using the one or more trained machine learning models and the request; and
causing the predicted feature data to be rendered at a graphical user interface (GUI) to suggest a predicted feature to be included with the selected feature at the computerized representation of the physical structure.
